(19) United States
(12) Patent Application Publication
(10) Pub. No.: US 2026/0123235 A1
(43) Pub. Date: Apr. 30, 2026

(54) DISPLAY DEVICE, ELECTRONIC DEVICE AND METHOD FOR MANUFACTURING DISPLAY DEVICE

(71) Applicant: Samsung Display Co., Ltd., Yongin-si (KR)

(72) Inventors: HWI KIM, Yongin-si (KR); JI-HEE SON, Yongin-si (KR); SEOULKI LEE, Yongin-si (KR); JOONGU LEE, Yongin-si (KR)

(21) Appl. No.: 19/275,804

(22) Filed: Jul. 21, 2025

(30) Foreign Application Priority Data
Oct. 31, 2024 (KR) 10-2024-0152060

(51) Int. Cl. H10K 59/80; H10K 50/17; H10K 59/12; H10K 71/60; H10K 102/00

(52) U.S. Cl. CPC H10K 59/80518; H10K 50/171; H10K 59/1201; H10K 59/80515; H10K 71/60; H10K 2102/351

(57) ABSTRACT

A display device includes: a substrate; a circuit layer on the substrate; a first electrode on the circuit layer; a light-emitting layer on the first electrode; an electron functional layer on the light-emitting layer; a second electrode on the electron functional layer, and having an integral shape; and a stabilization layer covering the second electrode. The second electrode includes: a first portion adjacent to the electron functional layer; a second portion adjacent to the stabilization layer; and a third portion between the first portion and the second portion, and having a greater density than that of the second portion. At least a part of an upper surface of the second electrode has a concave and convex structure.

### CROSS-REFERENCE TO RELATED APPLICATION

The present application claims priority to and the benefit of Korean Patent Application No. 10-2024-0152060, filed on Oct. 31, 2024, in the Korean Intellectual Property Office, the entire disclosure of which is incorporated by reference herein.

### BACKGROUND

### 1. Field

Aspects of embodiments of the present disclosure relate to a display device having improved reliability and side-visibility, an electronic device, and a method of manufacturing the display device.

### 2. Description of the Related Art

An organic light-emitting display device has self-light-emitting characteristics, and unlike a liquid crystal display device, a separate light source is not required or used, so that a weight and a thickness thereof may be reduced. In addition, the organic light-emitting display device may have low power consumption, high luminance, and a high reaction rate.

The above information disclosed in this Background section is for enhancement of understanding of the background of the present disclosure, and therefore, it may contain information that does not constitute prior art.

### SUMMARY

Recently, organic light-emitting display devices having improved side visibility to implement high-quality colors regardless of a user's visibility may be desired.

One or more embodiments of the present disclosure may be directed to a display device having improved reliability and side-visibility.

One or more embodiments of the present disclosure may be directed to an electronic device having improved reliability and side-visibility.

One or more embodiments of the present disclosure may be directed to a manufacturing method for a display device having improved reliability and side-visibility.

According to one or more embodiments of the present disclosure a display device includes: a substrate; a circuit layer on the substrate; a first electrode on the circuit layer; a light-emitting layer on the first electrode; an electron functional layer on the light-emitting layer; a second electrode on the electron functional layer, and having an integral shape; and a stabilization layer covering the second electrode. The second electrode includes: a first portion adjacent to the electron functional layer; a second portion adjacent to the stabilization layer; and a third portion between the first portion and the second portion, and having a greater density than that of the second portion. At least a part of an upper surface of the second electrode has a concave and convex structure.

In an embodiment, the upper surface of the second electrode may have a root-mean-square roughness that is greater than or equal to 2.5 nm and smaller than or equal to 6.0 nm.

In an embodiment, the first portion may have a smaller density than that of the third portion; and at least a part of a lower surface of the second electrode may have a concave and convex structure.

In an embodiment, the lower surface of the second electrode may have a root-mean-square roughness that is greater than or equal to 2.5 nm and smaller than or equal to 6.0 nm.

In an embodiment, the first portion, the second portion, and the third portion may include pure Ag.

In an embodiment, the stabilization layer may include a metal or a metal oxide.

In an embodiment, the stabilization layer may include ytterbium (Yb).

In an embodiment, the electron functional layer may include at least one electron injection layer; and the at least one electron injection layer may include ytterbium (Yb).

In an embodiment, a thickness of the electron injection layer may be greater than or equal to 5 Å and smaller than or equal to 30 Å.

In an embodiment, a thickness of the second electrode may be greater than or equal to 50 Å and smaller than or equal to 300 Å.

In an embodiment, the second electrode may further include: a fourth portion between the first portion and the third portion, and having a greater density than that of the first portion; and a fifth portion between the fourth portion and the third portion, and having a smaller density than that of the third portion.

According to one or more embodiments of the present disclosure, a manufacturing method for a display device, includes: preparing a preliminary display panel by forming a circuit layer, a first electrode, and a light-emitting layer on a substrate; forming an electron functional layer including at least one electron injection layer on the light-emitting layer; forming a second electrode on the electron functional layer; and forming a stabilization layer to cover the second electrode. The second electrode includes: a first portion adjacent to the electron functional layer; a second portion adjacent to the stabilization layer; and a third portion between the first portion and the second portion. The forming of the second electrode includes: forming the first portion on the electron functional layer at a first deposition rate; forming the third portion on the first portion at a third deposition rate greater than the first deposition rate; and forming the second portion on the third portion at a second deposition rate smaller than the third deposition rate. In the forming of the second portion, a part of an upper surface of the second electrode is formed to have a root-mean-square roughness that is greater than or equal to 2.5 nm and smaller than or equal to 6.0 nm.

In an embodiment, in the forming of the first portion, a part of a lower surface of the second electrode may be formed to have a root-mean-square roughness that is greater than or equal to 2.0 nm and smaller than or equal to 6.0.

In an embodiment, the first portion, the second portion, and the third portion may include pure Ag.

In an embodiment, the second electrode may be formed through vacuum thermal deposition.

In an embodiment, in the forming of the second electrode, the second electrode may be formed in a single chamber through a single process.

According to one or more embodiments of the present disclosure, a display device includes: a substrate; a circuit layer on the substrate; a first electrode on the circuit layer; a light-emitting layer on the first electrode; an electron functional layer on the light-emitting layer; a second electrode on the electron functional layer, and having an integral shape; and a stabilization layer covering the second electrode. The second electrode includes: a first portion adjacent to the electron functional layer; and a second portion adjacent to the stabilization layer, and having a greater density than that of the first portion. At least a part of a lower surface of the second electrode may have a concave and convex structure.

In an embodiment, the second electrode may further include a third portion on the second portion, and the third portion may have a smaller density than that of the second portion. At least a part of an upper surface of the second electrode may have a concave and convex structure.

In an embodiment, the upper surface of the second electrode may have a root-mean-square roughness that is greater than or equal to 2.0 nm and smaller than or equal to 6.0 nm; the lower surface of the second electrode may have a root-mean-square roughness that is greater than or equal to 2.0 nm and smaller than or equal to 6.0 nm; and the first portion, the second portion, and the third portion may include pure Ag.

According to one or more embodiments of the present disclosure, an electronic device includes: a substrate; a circuit layer on the substrate; a first electrode on the circuit layer; a light-emitting layer on the first electrode; an electron functional layer on the light-emitting layer; a second electrode on the electron functional layer, and having an integral shape; and a stabilization layer covering the second electrode. The second electrode includes: a first portion adjacent to the electron functional layer; a second portion adjacent to the stabilization layer; and a third portion between the first portion and the second portion, and having a greater density than that of the second portion. At least a part of an upper surface of the second electrode has a concave and convex structure.

According to some embodiments of the present disclosure, a display device having a concave and convex structure, and including an element having a high film density to increase a reliability and a side-visibility thereof, a manufacturing method for the display device, and an electronic device, may be provided.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a plan view schematically illustrating a display device according to an embodiment of the present disclosure;

FIG. 2 is a cross-sectional view taken along the line I-I′ of FIG. 1;

FIG. 3 is a cross-sectional view illustrating a portion of a display device according to an embodiment of the present disclosure;

FIG. 4 is graph showing a color change of samples of a display device per angle of sight;

FIG. 5 is a magnified view of the region AA shown in FIG. 2 according to an embodiment;

FIG. 6 is a magnified view of the region AA shown in FIG. 2 according to an embodiment;

FIG. 7 is a magnified view of the region AA shown in FIG. 2 according to an embodiment;

FIG. 8 is a flow chart of a manufacturing method for a display device according to an embodiment;

FIG. 9 is a flow chart of a portion of a manufacturing method for a display device according to an embodiment;

FIGS. 10A-10G are cross-sectional views schematically illustrating some processes of a manufacturing method for a display device according to an embodiment;

FIG. 11 illustrates various electronic devices that may be applied with a display device according to some embodiments of the present disclosure; and

FIG. 12 illustrates an electronic device that may be applied with a display device according to some embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

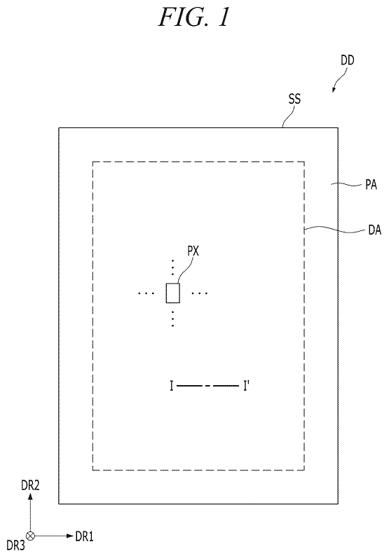

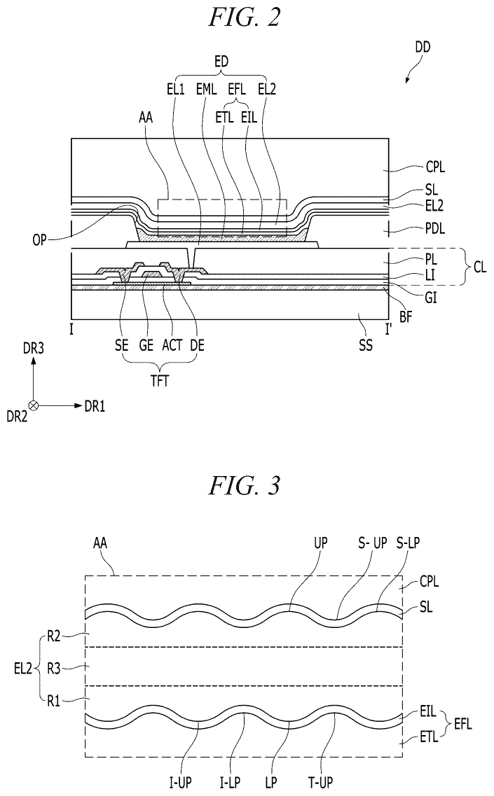

FIG. 1 is a plan view schematically illustrating a display device according to an embodiment of the present disclosure. FIG. 2 is a cross-sectional view taken along the line I-I′ of FIG. 1.

In FIGS. 1 and 2, a first direction through a third direction DR1, DR2 and DR3 are illustrated. The first direction DR1 and the second direction DR2 may be directions intersecting or crossing each other, and defining a plane of the display device DD as shown in FIG. 1. The third direction DR3 may be a thickness direction of the display device DD as shown in FIG. 2.

Referring to FIG. 1, the display device DD may have a display area DA and a peripheral area PA defined therein. The display device DD may include a substrate SS. In this case, the display area DA and the peripheral area PA may be regions defined on the substrate SS.

The display area DA of the substrate SS may have a plurality of pixels PX including light-emitting diodes, such as organic light-emitting diodes, arranged therein. The pixels PX may include thin-film transistors for controlling the light-emitting diodes. Each pixel PX may include at least one thin-film transistor.

The peripheral area PA of the substrate SS may include various suitable wirings arranged therein for transferring electrical signals applied to the display area DA. The peripheral area PA may include a thin-film transistor disposed therein, and the thin-film transistor may be part of a circuit unit (e.g., a circuit) for controlling electrical signals applied to the display area DA.

Referring to FIG. 2, a display device according to an embodiment of the present disclosure may include the substrate SS, a circuit layer CL, a pixel defining layer PDL, a light-emitting diode ED, a stabilization layer SL, and a capping layer CPL.

The substrate SS may be formed from various suitable materials, such as glass, a metal, or a plastic. In an embodiment, the substrate SS may be a flexible substrate. For example, the substrate SS may include one or more polymer resins, such as polyethersulfone (PES), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), or cellulose acetate propionate (CAP).

The circuit layer CL may be disposed on the substrate SS, and may include a thin-film transistor TFT, a gate insulating layer GI, an interlayer insulating layer LI, and a planarization layer PL.

The thin-film transistor TFT may include an active layer ACT, a gate electrode GE, a source electrode SE, and a drain electrode DE. The gate insulating layer GI may be disposed between the gate electrode GE and the active layer ACT for insulation between the gate electrode GE and the active layer ACT.

The active layer ACT may be disposed on the buffer layer BF. The active layer ACT may be made from one or more inorganic semiconductors, such as amorphous silicon or polycrystalline silicon, or from one or more organic semiconductors. In some embodiments, the active layer ACT may be formed from an oxide semiconductor. For example, the oxide semiconductor may include one or more oxides of various suitable materials selected from groups 12, 13, and/or 14, metal elements, such as zinc (Zn), indium (In), gallium (Ga), tin (Sn), cadmium (Cd), germanium (Ge), or hafnium (Hf), or suitable combinations thereof.

The gate insulating layer GI may be disposed on the buffer layer BF, and may cover the active layer ACT. The gate electrode GE may be disposed on the gate insulating layer GI.

The interlayer insulating layer LI may be disposed on the gate insulating layer GI and the gate electrode GE, and may cover the gate electrode GE. The source electrode SE and the drain electrode DE may be formed on the interlayer insulating layer LI, and may each contact the active layer ACT through a corresponding contact hole.

However, the structure of the thin-film transistor TFT is not limited to that described above, and various suitable kinds of transistor structures may be applied. For example, although the thin-film transistor TFT formed in a top gate structure is illustrated, in another example, the thin-film transistor TFT may be formed in a bottom gate structure in which the gate electrode GE is disposed under the active layer ACT.

The planarization layer PL may be disposed on the source electrode SE, the drain electrode DE, and the interlayer insulating layer LI. The light-emitting diode ED may be disposed on the planarization layer PL. The light-emitting diode ED may include a first electrode EL1, a light-emitting layer EML, an electron functional layer EFL, and a second electrode EL2.

The planarization layer PL may provide a flat or substantially flat upper surface, so that the first electrode EL1 may be formed evenly flat. The planarization layer PL may be formed from a single layer or multiple layers of organic or inorganic materials. The planarization layer PL may include common polymer materials, such as benzocyclobutene (BCB), polyimide (PI), hexamethyldisiloxane (HMDSO), polymethylmethacrylate (PMMA), or polystyrene (PS), polymer derivatives with phenolic groups, acrylic polymers, imide polymers, aryl ether polymers, amide polymers, fluorine-based polymers, p-xylylene polymers, vinyl alcohol-based polymers, or suitable blends thereof. The planarization layer PL may include silicon oxide (SiO₂), silicon nitride (SiNx), silicon oxynitride (SiON), aluminum oxide (Al₂O₃), titanium oxide (TiO₂), tantalum oxide (Ta₂O₅), hafnium oxide (HfO₂), or zinc oxide (ZnO₂). After forming the planarization layer PL, chemical and/or mechanical polishing may be performed to provide a flat or substantially flat upper surface.

The planarization layer PL may include an opening that exposes either the source electrode SE or the drain electrode DE of the thin-film transistor TFT. The first electrode EL1 may contact the source electrode SE or drain electrode DE through the opening, and may be electrically connected to the thin-film transistor TFT.

A display device according to an embodiment may further include the buffer layer BF disposed between the circuit layer CL and the substrate SS. The buffer layer BF may prevent or substantially prevent the diffusion of impurity ions into the substrate SS, may block moisture and air infiltration, and may planarize or substantially planarize a surface. In some embodiments, the buffer layer BF may be formed from inorganic materials, such as silicon oxide, silicon nitride, silicon oxynitride, aluminum oxide, aluminum nitride, titanium oxide, or titanium nitride, or from organic materials, such as polyimide, polyester, or acrylic, or a suitable laminated structure thereof.

The light-emitting diode ED is disposed on the planarization layer PL, and may include the first electrode EL1, the second electrode EL2 opposite the first electrode EL1, the light-emitting layer EML disposed between the first electrode EL1 and the second electrode EL2, and the electron functional layer EFL disposed on the light-emitting layer EML.

The first electrode EL1 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the first electrode EL1 may include a reflective layer containing silver (Ag), magnesium (Mg), aluminum (Al), platinum (Pt), palladium (Pd), gold (Au), nickel (Ni), neodymium (Nd), iridium (Ir), chromium (Cr), or suitable compounds thereof. In an embodiment, the first electrode EL1 may further include a layer formed from ITO, IZO, ZnO, or In₂O₃ above or below the reflective layer. For example, the first electrode EL1 may have a multilayered structure of ITO/Ag/ITO.

A pixel defining layer PDL may be disposed on the first electrode EL1 and the planarization layer PL. The pixel defining layer PDL may define the pixels by having openings OP corresponding to the pixels, respectively. The pixel defining layer PDL may also increase a distance between the edges of the first electrode EL1 and the second electrode EL2 to prevent or substantially prevent an arcing between them. The pixel defining layer PDL may be formed from an organic material, such as polyimide or HMDSO.

The light-emitting layer EML may include an organic material containing fluorescent or phosphorescent substances that emit red, green, blue, or white light. The light-emitting layer EML may be a small molecule or a polymeric organic material, and functional layers, such as a hole transport layer (HTL) and a hole injection layer (HIL), may be selectively disposed below the light-emitting layer EML. The light-emitting layer EML may be disposed correspondingly for each of the plurality of first electrodes EL1. However, the present embodiment is not limited thereto, and the light-emitting layer EML may be integrally formed over the plurality of first electrodes EL1.

The electron functional layer EFL may be disposed on the light-emitting layer EML, and may include an electron injection layer EIL and an electron transport layer ETL. In an embodiment of the present disclosure, the electron injection layer EIL may protect a lower surface of the second electrode EL2, in addition to functioning as a functional layer.

According to an embodiment, the electron functional layer EFL may include at least one electron injection layer EIL, and the electron injection layer EIL may include ytterbium (Yb).

In an embodiment, a thickness of the electron injection layer EIL may be greater than or equal to 5 Å and smaller than or equal to 30 Å.

The electron functional layer EFL will be described in more detail below.

The second electrode EL2 may be a transparent or translucent electrode. The second electrode may be disposed across both the display area DA and the peripheral area PA, and on the light-emitting layer EML and the pixel defining layer PDL. The second electrode EL2 may be integrally formed for the plurality of light-emitting diodes ED to correspond to the plurality of first electrodes EL1.

In an embodiment, the second electrode EL2 may be provided with pure Ag.

In an embodiment, a thickness of the second electrode EL2 may be greater than or equal to 50 Å and smaller than or equal to 300 Å.

The second electrode EL2 will be described in more detail below.

Although the light-emitting diode ED is illustrated in FIG. 2 as including a single light-emitting layer EML, the present disclosure is not limited thereto. In an embodiment, the light-emitting diode may include n light-emitting structures laminated between the first electrode EL1 and the second electrode EL2, as well as n−1 charge generation layers, where n is a natural number greater than 1.

Each of the light-emitting structures may include a light-emitting layer EML, a hole functional layer, and an electron functional layer disposed with the light-emitting layer EML in between. In other words, the light-emitting diode included in the display device according to an embodiment may have a tandem structure including a plurality of light-emitting layers. A charge generation layer may be disposed between adjacent light-emitting structures. The charge generation layer may include a p-type charge generation layer and/or an n-type charge generation layer.

The stabilization layer SL may be disposed on the second electrode EL2 to cover the second electrode EL2. The stabilization layer SL may make direct contact with the second electrode EL2 to maintain a constant or substantially constant roughness of an upper surface UP (e.g., see FIG. 3) of the second electrode EL2.

In an embodiment, the stabilization layer SL may include a metal or a metal oxide.

In an embodiment, the stabilization layer SL may include ytterbium (Yb).

The stabilization layer SL will be described in more detail below.

The capping layer CPL may be disposed on the stabilization layer SL. The capping layer CPL may include organic and/or inorganic materials. When the capping layer CPL includes an organic material, the capping layer CPL may include α-NPD, NPB, TPD, m-MTDATA, Alq3, CuPc, TPD15 (N4,N4,N4′,N4′-tetra (biphenyl-4-yl) biphenyl-4,4′-diamine), TCTA (4,4′,4″-Tris (carbazol sol-9-yl) triphenylamine), an epoxy resin, or one or more acrylates, such as methacrylate. When the capping layer CPL includes an inorganic material, the capping layer CPL may include alkali metal compounds such as LiF, alkaline earth metal compounds such as MgF₂, silicon oxide SiO₂, silicon nitride SiNx, or silicon oxynitride SiON. The capping layer CPL may be a single layer or multiple layers.

FIG. 3 is a cross-sectional view illustrating a portion of a display device according to an embodiment of the present disclosure. In FIG. 3, for convenience of illustration, a portion of the display device including some of the lower elements thereof is not shown.

Referring to FIG. 3, in an embodiment, the second electrode EL2 may include a first portion R1 adjacent to the electron functional layer EFL, a second portion R2 adjacent to the stabilization layer SL, and a third portion R3 disposed between the first portion R1 and the second portion R2.

The first portion through the third portion R1, R2, and R3 of the second electrode EL2 may be formed at different deposition rates from one another, and accordingly, may have different densities from one another. In this case, the first portion R1 and the second portion R2 may be portions formed at a deposition rate that is slower than a deposition rate of the third portion R3. Accordingly, the third portion R3 may have a greater density than those of the first portion R1 and the second portion R2. The second electrode EL2 may include the third portion R3 having the greater density than those of the first portion R1 and the second portion R2, so that an overall film density of the second electrode EL2 may be increased. A display device according to an embodiment of the present disclosure may include the second electrode EL2 having an increased film density, so that a device efficiency and a device lifespan may be improved, and a reliability may be improved accordingly.

The second electrode EL2 according to an embodiment of the present disclosure may be provided with pure Ag having a strong cohesion. Because pure Ag may have a high surface energy, the smaller a deposition rate is, the more cohesion on a surface may occur. Accordingly, interfaces of the first portion R1 and the second portion R2 formed at a relatively lower deposition rate, or in other words, a lower surface LP and an upper surface UP of the second electrode EL2, may each have a concave and convex structure formed through a cohesion of pure Ag. The first portion through the third portion R1, R2, and R3 will be described in more detail below.

In an embodiment of the present disclosure, the concave and convex structure of the lower surface LP of the second electrode EL2 and/or the upper surface UP of the second electrode EL2 may diffuse light to be discharged to the outside of the display device DD to reduce a degree of a white angular dependency (WAD), and a side-visibility of the display device may be improved accordingly.

In another embodiment, the convex and concave structure of the lower surface LP of the second electrode EL2 may be also formed on the electron injection layer EIL. As illustrated in FIG. 3, the electron injection layer EIL may have a smaller thickness than that of the second electrode EL2. Accordingly, in a case in which a concave and convex structure is formed on the lower surface LP of the second electrode EL2, the lower elements of the second electrode EL2 may also be affected, so that an upper surface I-UP and a lower surface I-LP of the electron injection layer EIL and an upper surface T-UP of the electron transport layer ETL may have a concave and convex structure.

The concave and convex structure of the upper surface UP of the second electrode EL2 may also be formed on the stabilization layer SL. As illustrated in FIG. 3, the stabilization layer SL may have a smaller thickness than that of the second electrode EL2. Accordingly, according to the concave and convex structure formed on the upper surface UP of the second electrode EL2, a lower surface S-LP of the stabilization layer SL and an upper surface S-UP of the stabilization layer SL may also have a concave and convex structure.

In an embodiment, the upper surface UP of the second electrode EL2 may have a root-mean-square roughness that is greater than or equal to 2.0 nm and smaller than or equal to 6.0 nm, or in more detail, greater than or equal to 3.6 nm and smaller than or equal to 5.8 nm.

In a comparative example, an upper surface of a second electrode may have a root-mean-square roughness smaller than 2.0 nm. In a display device of the comparative example, a white angular dependency may occur a lot (e.g., may occur more often), and the display device may have a decreased side-visibility. In another comparative example, an upper surface of a second electrode may have a root-mean-square roughness greater than 6.0 nm. In this case, the second electrode may have a significantly lower film density, and thus, film contraction may occur under high temperature circumstances, and a reliability of the display device may be decreased.

In an embodiment, the lower surface LP of the second electrode EL2 may have a root-mean-square roughness that is greater than or equal to 2.0 nm and smaller than or equal to 6.0 nm, or in more detail, greater than or equal to 3.6 nm and smaller than or equal to 5.8 nm.

In a comparative example, a lower surface of a second electrode may have a root-mean-square roughness smaller than 2.0 nm. In a display device of the comparative example, a white angular dependency may occur a lot (e.g., may occur more often), and the display device may have a decreased side-visibility. In another comparative example, a lower surface of a second electrode may have a root-mean-square roughness greater than 6.0 nm. In this case, the second electrode may have a significantly lower film density, and thus, a film contraction may occur under high temperature circumstances, and a reliability of the display device may be decreased.

In an embodiment of the present disclosure, the lower surface LP and/or the upper surface UP of the second electrode EL2 may have a root-mean-square roughness that is greater than or equal to 2.0 nm and smaller than or equal to 6.0 nm, or in more detail, greater than or equal to 3.6 nm and smaller than or equal to 5.8 nm. A change in the root-mean-square roughness within the above-described range and a degree of an occurrence of a white angular dependency (WAD) may have a trade-off relationship with each other.

The white angular dependency (WAD) may refer to a phenomenon in which white light is emitted from an organic light-emitting display device, and the white light is visible as white light in the front, but may be visible as blue light from the side due to a wavelength shift of the light. When a degree of the white light wavelength shift is decreased, a side-visibility may be improved.

In a case in which a root-mean-square roughness is increased, a film density may be decreased. However, a degree of the white light wavelength shift may also be decreased, and a side-visibility may be improved. On the other hand, in a case in which a root-mean-square is decreased, a film density may be increased. However, a degree of the white light wavelength shift may also be increased, and a side-visibility may be decreased. Accordingly, a root-mean-square of the upper surface UP of the second electrode EL2 or the lower surface LP of the second electrode EL2 may be selectively controlled to be in a range greater than or equal to 2.0 nm and smaller than or equal to 6.0 nm, or in more detail, greater than and equal to 3.6 nm and smaller than or equal to 5.8 nm, by controlling a deposition rate of the first portion R1 and the second portion R2.

In an embodiment of the present disclosure, the second electrode EL2 may be provided with pure Ag. Because pure Ag may have a high surface energy, in a case in which a deposition rate is below a point (e.g., a certain or predetermined point), a cohesion may occur on the lower surface LP and/or the upper surface UP of the second electrode EL2. The electron injection layer EIL and the stabilization layer SL may stabilize the lower surface LP and the upper surface UP of the second electrode EL2 to maintain a constant or substantially constant roughness.

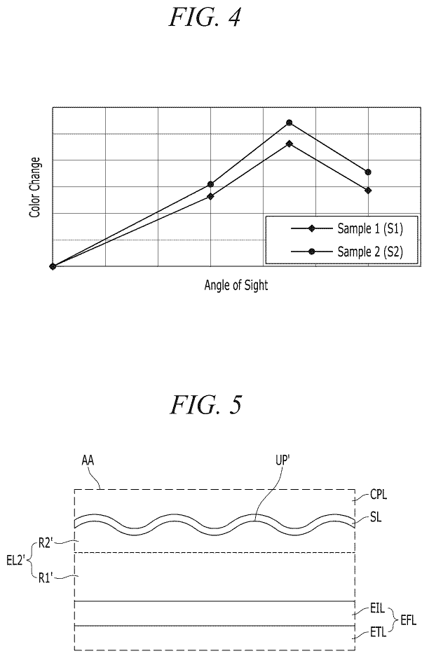

FIG. 4 is graph showing a color change of samples of a display device per angle of sight.

A first sample S1 shown in FIG. 4 may be a sample of a display device including a second electrode deposited at a deposition rate slower than a deposition rate of the second electrode deposited in a second sample S2 shown in FIG. 4. The first sample S1 and the second sample S2 may both be provided with pure Ag.

Referring to FIG. 4, the first sample S1 involved a less occurrence of a white light wavelength shift, and showed a less color change per angle of sight than those of the second sample S2. The second electrode of the first sample S1 has a greater surface roughness than that of the second electrode of the second sample S2, and the surface has a concave and convex structure. Accordingly, a white light wavelength shift occurred relatively less with the first sample S1 compared to the second sample S2, which shows an improvement of a side-visibility.

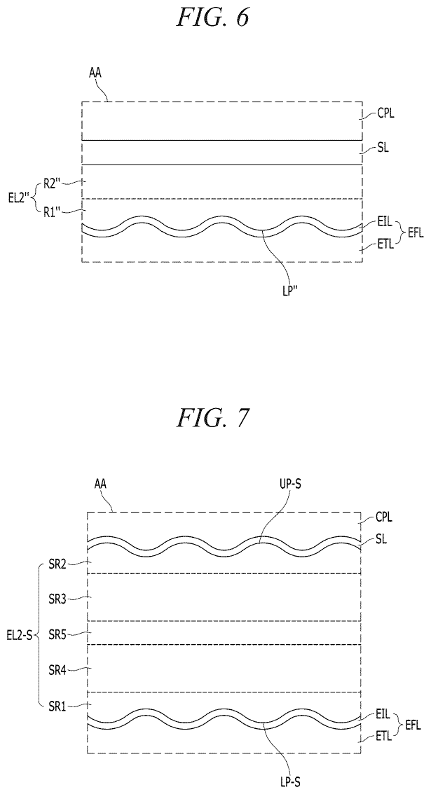

FIG. 5 is a magnified view of the region AA shown in FIG. 2 according to an embodiment. FIG. 6 is a magnified view of the region AA shown in FIG. 2 according to an embodiment. FIG. 7 is a magnified view of the region AA shown in FIG. 2 according to an embodiment.

Referring to FIG. 5, in an embodiment, the second electrode EL2′ includes a first portion R1′ and a second portion R2′. The first portion R1′ may be adjacent to the electron functional layer EFL, and may have a greater density than that of the second portion R2′. The second portion R2′ may be disposed on the first portion R1′, and may be adjacent to the stabilization layer SL. An upper surface UP′ of the second electrode EL2′ may have a concave and convex structure.

In an embodiment, the concave and convex structure of the upper surface UP′ of the second electrode EL2′ may diffuse light to be discharged to outside of the display device DD to reduce a degree of a white angular dependency, and a side-visibility of the display device may be improved accordingly.

Referring to FIG. 6, in an embodiment, the second electrode EL2″ may include a first portion R1″ and a second portion R2″. The first portion R1″ may be adjacent to the electron functional layer EFL, and may have a smaller density than that of the second portion R2″. The second portion R2″ may be disposed on the first portion R1″, and may be adjacent to the stabilization layer SL. A lower surface LP″ of the second electrode EL2″ may have a concave and convex structure.

In an embodiment, the concave and convex structure of the lower surface LP″ of the second electrode EL2″ may diffuse light to be discharged to outside of the display device DD to reduce a degree of a white angular dependency, and a side-visibility of the display device may be improved accordingly.

Referring to FIG. 7, in an embodiment, the second electrode EL2-S may include a first portion through a fifth portion SR1, SR2, SR3, SR4, and SR5. The first portion SR1 may be adjacent to the electron functional layer EFL, and the second portion SR2 may be adjacent to the stabilization layer SL. The third portion SR3, the fourth portion SR4, and the fifth portion SR5 may be disposed between the first portion SR1 and the second portion SR2. The third portion SR3 and the fourth portion SR4 may be portions having a greater density than those of the other portions SR1, SR2, and SR5.

The second electrode EL2-S may include the first portion SR1 and the second portion SR2 disposed to be adjacent to a lower surface LP-S of the second electrode EL2-S and an upper surface UP-S of the second electrode EL2-S, respectively, and having a relatively smaller density. In addition, the second electrode EL2-S may include the third portion SR3 and the fourth portion SR4 disposed between the first portion SR1 and the second portion SR2, and having a relatively greater density. In addition, the second electrode EL2-S may include the fifth portion SR5 disposed between the third portion SR3 and the fourth portion SR4, and having a relatively smaller density.

Although FIG. 7 illustrates that the second electrode EL2-S includes the first portion through the fifth portion SR1, SR2, SR3, SR4, and SR5, the present disclosure is not limited thereto. In another embodiment, the second electrode may include a first portion having a relatively smaller density and disposed adjacent to the electron functional layer, and a second portion having a relatively smaller density and disposed adjacent to the stabilization layer, and may have a sandwich structure having n portions having a relatively smaller density and n+1 portions having a relatively greater density alternatingly arranged between the first portion and the second portion. Here, n is a natural number.

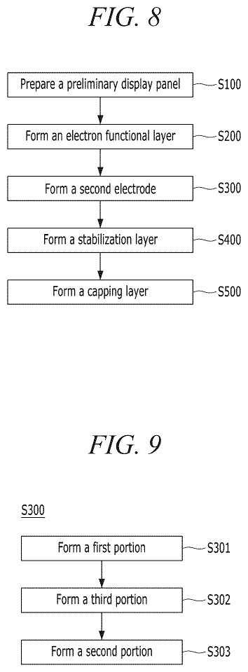

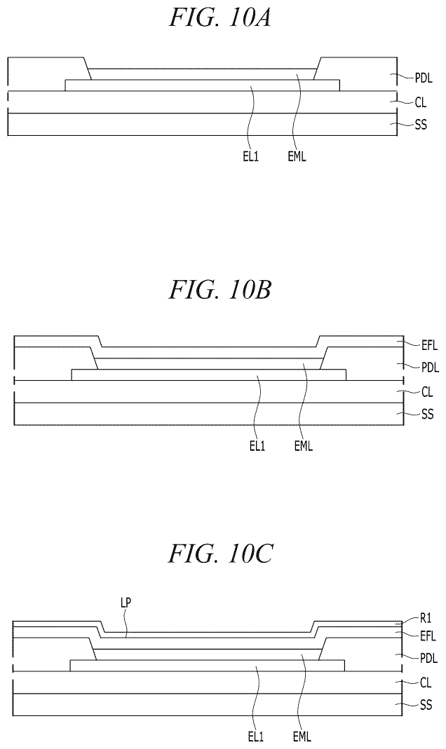

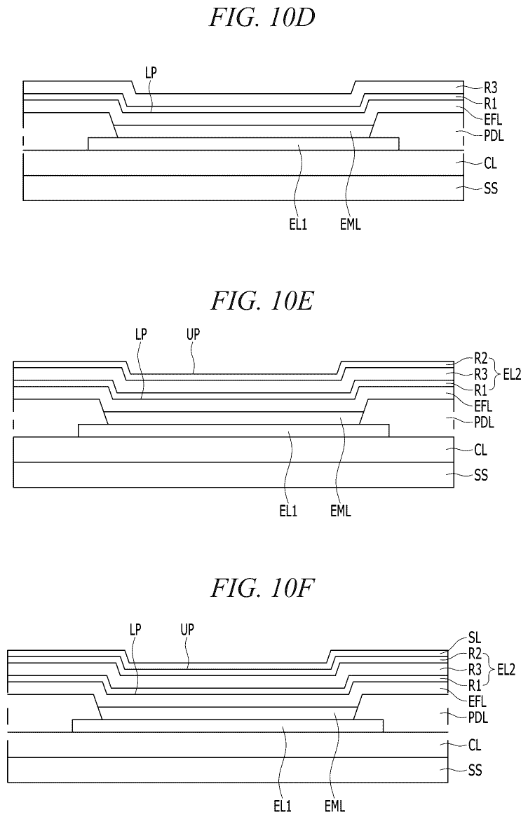

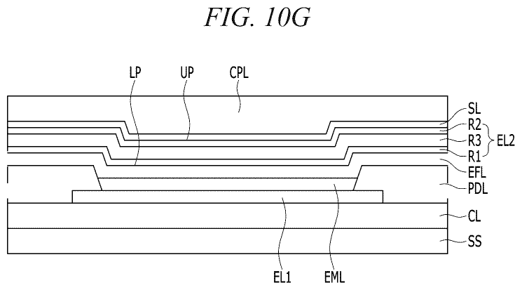

FIG. 8 is a flow chart of a manufacturing method for a display device according to an embodiment. FIG. 9 is a flow chart of a portion of a manufacturing method for a display device according to an embodiment. FIGS. 10A through 10G are cross-sectional views schematically illustrating some processes of a manufacturing method for a display device according to an embodiment.

Referring to FIG. 8, the manufacturing method for a display device according to an embodiment may include preparing a preliminary display panel (S100), forming an electron functional layer (S200), forming a second electrode (S300), forming a stabilization layer (S400), and forming a capping layer (S500).

Referring to FIGS. 8 and 10A, in the preparing of the preliminary display panel (S100), a circuit layer CL including a transistor and a planarization layer may be formed on a substrate SS, a first electrode EL1 and a pixel defining film PDL may be formed on the circuit layer CL, and a light-emitting layer EML may be formed on the first electrode EL1 and the pixel defining film PDL, to prepare the preliminary display panel.

Referring to FIGS. 8 and 10B, in the forming of the electron functional layer (S200), an electron functional layer EFL may be formed on the pixel defining film PDL and the light-emitting layer EML. In an embodiment, the electron functional layer EFL may include at least one electron injection layer EIL.

Referring to FIGS. 8 and 9, in an embodiment, the forming of the second electrode EL2 (S300) may include forming a first portion (S301), forming a third portion (S302), and forming a second portion (S303).

Referring to FIGS. 9 and 10C, in an embodiment, in the forming of the first portion (S301), pure Ag may be used to form the first portion R1. In this case, pure Ag having a high surface energy may be deposited at a first deposition rate to form the first portion R1, and a concave and convex structure may be formed on a lower surface LP of the second electrode EL2. The first deposition rate may be 2.0 Å/s, and the first deposition rate may be a deposition rate allowing a concave and convex structure to be formed on the lower surface LP of the second electrode. In this case, the lower surface LP of the second electrode may have a root-mean-square roughness that is greater than or equal to 2.0 nm and smaller than or equal to 6.0 nm, or in more detail, greater than or equal to 3.6 nm and smaller than or equal to 5.8 nm.

However, the present disclosure is not limited thereto. In another embodiment, the first portion R1 may be deposited at a rate, for example, such as 3.0 Å/s, that is greater than the first deposition rate, and the lower surface LP of the second electrode EL2 may not have the concave and convex structure.

Referring to FIGS. 9 and 10D, in an embodiment, in the forming of the third portion (S302), the third portion R3 may be formed on the first portion R1 at a second deposition rate greater than the first deposition rate. The second deposition rate may be 3.0 Å/s. The third portion R3 formed at the second deposition rate greater than the first deposition rate may have a greater density than that of the first portion R1. However, the present disclosure is not limited thereto, and in another embodiment, the forming of the third portion (S302) may be omitted as needed or desired.

Referring to FIGS. 9 and 10E, in an embodiment, in the forming of the second portion (S303), the second portion R2 may be formed at a third deposition rate slower than the second deposition rate. The third deposition rate may be 2.0 Å/s. The third deposition rate may be a deposition rate allowing a cohesion of pure Ag to form a concave and convex structure on an upper surface of the second electrode. In this case, the upper surface of the second electrode may have a root-mean-square roughness that is greater than or equal to 2.0 nm and smaller than or equal to 6.0 nm, or in more detail, greater than or equal to 3.6 nm and smaller than or equal to 5.8 nm.

However, the present disclosure is not limited thereto. In another embodiment, a first deposition rate for forming the first portion R1 may be a deposition rate allowing a concave and convex structure to be formed on a lower surface of the second electrode. In this case, a third deposition rate for forming the second portion R2 may be greater than the first deposition rate, and the upper surface of the second electrode may not have a concave and convex structure.

In an embodiment of the present disclosure, an upper surface and/or a lower surface of the second electrode may have a concave and convex structure, and the second electrode may include another portion that is formed at a greater deposition rate than those of any of the portions adjacent to the upper surface and/or the lower surface of the second electrode, and having a greater density than those of any of the portions.

In an embodiment of the present disclosure, in the forming of the second electrode (S300), the second electrode EL2 may be formed in a single chamber through a single process. The single process may refer to a process series of successively forming a first portion through a third portion R1, R2, and R3 with pure Ag by changing a deposition rate. However, the present disclosure is not limited thereto, and the single process may be a process of forming a number of layers having a different density from one another by changing a deposition rate several times.

Referring to FIGS. 8 and 10F, in the forming of the stabilization layer (S400), the stabilization layer SL covering the second electrode EL2 may be formed. The stabilization layer SL may include a metal or a metal oxide. In some embodiments, the stabilization layer SL may include ytterbium (Yb).

Referring to FIGS. 8 and 10G, in the forming of the capping layer (S500), the capping layer CPL may be formed on the stabilization layer SL.

Through the manufacturing method for the display device according to an embodiment of the present disclosure, a second electrode may be formed so that an upper surface and/or a lower surface of the second electrode has a concave and convex structure. Accordingly, a white light wavelength dependency of a display device may be reduced, and a side-visibility may be improved. In addition, another portion having a greater density than that of a portion adjacent to the upper surface or the lower surface of the second electrode having the concave and convex structure may be formed on the second electrode. Accordingly, an overall film density of the second electrode may be increased, and therefore, a reliability of the display device may be improved.

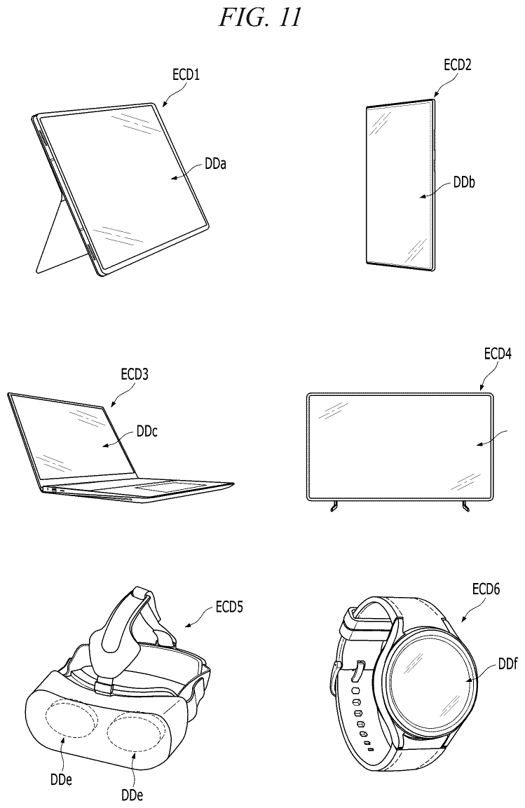

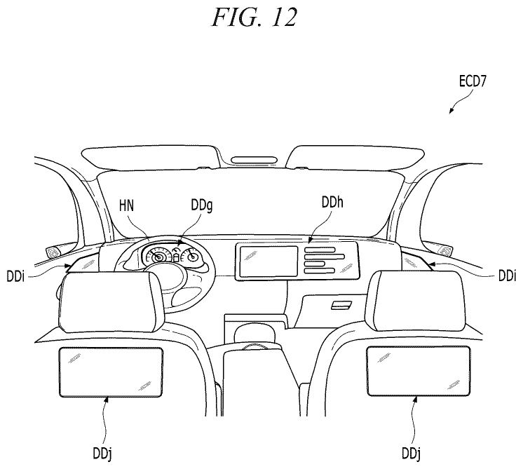

FIG. 11 illustrates various electronic devices that may be applied with a display device according to some embodiments of the present disclosure. FIG. 12 illustrates an electronic device that may be applied with a display device according to some embodiments of the present disclosure.

Referring to FIG. 11, a first electronic device ECD1 is illustrated as a tablet PC including a first display device DDa. A second electronic device ECD2 is illustrated as a portable terminal including a second display device DDb. A third electronic device ECD3 is illustrated as a laptop including a third display device DDc. A fourth electronic device ECD4 is illustrated as a television including a fourth display device DDd.

A fifth electronic device ECD5 is illustrated as a head-mounted display device including a fifth display device DDe. A sixth electronic device ECD6 is illustrated as a digital watch including a sixth display device DDf.

Referring to FIG. 12, a seventh electronic device ECD7 is illustrated as a vehicle including a seventh display device through a tenth display device DDg through DDj. The seventh electronic device ECD7 is illustrated as an automobile as a representative example, but the present disclosure is not limited thereto, and the electronic device may be any suitable kind of transportation means, such as a bicycle, a motorcycle, a train, a ship, or a plane.

The seventh display device DDg may be disposed in front of a wheel HN in a driver's sight for utilization in showing instrument panel information, such as a driving speed of the vehicle. The eighth display device DDh may be disposed on a dashboard of a vehicle, spaced apart from the seventh display device DDg, and utilized in showing information about a vehicle control interface, audio, temperature, road condition, and/or video. The ninth display device DDi may be disposed on a side mirror of a driver seat or a passenger seat, and utilized as a digital side mirror. The ninth display device DDi may display an image by filming the outside of a vehicle. The tenth display device DDj may be disposed behind a driver seat or a passenger seat, and utilized in displaying, for example, an image, which may be recognized by a passenger in a rear seat.

The electronic devices according to some embodiments of the present disclosure are not limited to the examples shown in FIGS. 11 and 12, and the display device DD according to some embodiments of the present disclosure may be applicable to any suitable electronic device in any suitable field. For example, The display device DD may be applicable to various suitable electronic devices, such as a printer, a telephone, a wearable device, a digital camera, a camcorder, a viewfinder, a 3D display, a video wall including a tiled display, a theater, a signboard, a medical instrument, memory, a memory processor, and a storage.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
a circuit layer on the substrate;
a first electrode on the circuit layer;
a light-emitting layer on the first electrode;
an electron functional layer on the light-emitting layer;
a second electrode on the electron functional layer, and having an integral shape; and
a stabilization layer covering the second electrode,
wherein the second electrode comprises:
a first portion adjacent to the electron functional layer; and
a second portion adjacent to the stabilization layer, and
wherein at least one of at least a part of an upper surface of the second electrode or at least a part of a lower surface of the second electrode has a concave and convex structure.

2. The display device of claim 1, wherein the upper surface of the second electrode has the concave and convex structure, and the upper surface of the second electrode has a root-mean-square roughness that is greater than or equal to 2.5 nm and smaller than or equal to 6.0 nm.

3. The display device of claim 1, wherein the upper surface of the second electrode has the concave and convex structure,
wherein the second electrode further comprises a third portion between the first portion and the second portion, and having a greater density than that of the second portion, and
wherein:
the first portion has a smaller density than that of the third portion; and
the at least the part of the lower surface of the second electrode also has the concave and convex structure.

4. The display device of claim 3, wherein the lower surface of the second electrode has a root-mean-square roughness that is greater than or equal to 2.5 nm and smaller than or equal to 6.0 nm.

5. The display device of claim 3, wherein the first portion, the second portion, and the third portion comprise pure Ag.

6. The display device of claim 1, wherein the stabilization layer comprises a metal or a metal oxide.

7. The display device of claim 6, wherein the stabilization layer comprises ytterbium (Yb).

8. The display device of claim 1, wherein:
the electron functional layer comprises at least one electron injection layer; and
the at least one electron injection layer comprises ytterbium (Yb).

9. The display device of claim 8, wherein a thickness of the electron injection layer is greater than or equal to 5 Å and smaller than or equal to 30 Å.

10. The display device of claim 1, wherein a thickness of the second electrode is greater than or equal to 50 Å and smaller than or equal to 300 Å.

11. The display device of claim 1, wherein the second electrode further comprises:
a third portion between the first portion and the second portion, and having a greater density than that of the second portion;
a fourth portion between the first portion and the third portion, and having a greater density than that of the first portion; and
a fifth portion between the fourth portion and the third portion, and having a smaller density than that of the third portion.

12. A manufacturing method for a display device, comprising:
preparing a preliminary display panel by forming a circuit layer, a first electrode, and a light-emitting layer on a substrate;
forming an electron functional layer comprising at least one electron injection layer on the light-emitting layer;
forming a second electrode on the electron functional layer; and
forming a stabilization layer to cover the second electrode,
wherein the second electrode comprises:
a first portion adjacent to the electron functional layer;
a second portion adjacent to the stabilization layer; and
a third portion between the first portion and the second portion,
wherein the forming of the second electrode comprises:
forming the first portion on the electron functional layer at a first deposition rate;
forming the third portion on the first portion at a third deposition rate greater than the first deposition rate; and
forming the second portion on the third portion at a second deposition rate smaller than the third deposition rate, and
wherein, in the forming of the second portion, a part of an upper surface of the second electrode is formed to have a root-mean-square roughness that is greater than or equal to 2.5 nm and smaller than or equal to 6.0 nm.

13. The manufacturing method of claim 12, wherein, in the forming of the first portion, a part of a lower surface of the second electrode is formed to have a root-mean-square roughness that is greater than or equal to 2.0 nm and smaller than or equal to 6.0.

14. The manufacturing method of claim 12, wherein the first portion, the second portion, and the third portion comprise pure Ag.

15. The manufacturing method of claim 12, wherein the second electrode is formed through vacuum thermal deposition.

16. The manufacturing method of claim 12, wherein, in the forming of the second electrode, the second electrode is formed in a single chamber through a single process.

17. The display device of claim 1, wherein the second portion has a greater density than that of the first portion, and
wherein the at least the part of the lower surface of the second electrode has the concave and convex structure.

18. The display device of claim 17, wherein:
the second electrode further comprises a third portion on the second portion, and the third portion has a smaller density than that of the second portion; and
at least a part of an upper surface of the second electrode has a concave and convex structure.

19. The display device of claim 18, wherein:
the upper surface of the second electrode has a root-mean-square roughness that is greater than or equal to 2.0 nm and smaller than or equal to 6.0 nm;
the lower surface of the second electrode has a root-mean-square roughness that is greater than or equal to 2.0 nm and smaller than or equal to 6.0 nm; and
the first portion, the second portion, and the third portion comprise pure Ag.

20. An electronic device comprising:
a substrate;
a circuit layer on the substrate;
a first electrode on the circuit layer;
a light-emitting layer on the first electrode;
an electron functional layer on the light-emitting layer;
a second electrode on the electron functional layer, and having an integral shape; and
a stabilization layer covering the second electrode,
wherein the second electrode comprises:
a first portion adjacent to the electron functional layer;
a second portion adjacent to the stabilization layer; and
a third portion between the first portion and the second portion, and
having a greater density than that of the second portion, and
wherein at least a part of an upper surface of the second electrode has a concave and convex structure.
